(19) United States
(12) Patent Application Publication
(10) Pub. No.: US 2014/0002316 A1
(43) Pub. Date: Jan. 2, 2014

(54) Communication Device and Antenna Testing Device

(71) Applicant: Wei Liu, Beijing (CN)

(72) Inventor: Wei Liu, Beijing (CN)

(73) Assignee: ST-Ericsson Semiconductor (Beijing) Co., Ltd., Beijing (CN)

(21) Appl. No.: 13/885,506

(22) PCT Filed: Nov. 14, 2011
(86) PCT No.: PCT/CN2011/082134

§ 371 Date: Sep. 23, 2013

(30) Foreign Application Priority Data
Nov. 16, 2010 (CN) 201010547217.6

(51) Int. Cl. G01R 31/04

(52) U.S. Cl. CPC G01R 31/04
USPC 343/703

(57) ABSTRACT

A communication device may comprise a radio frequency (RF) matching circuit, an antenna port, an antenna, a first blocking part, a second blocking part, a detecting port, and a reference level providing part. The first blocking part may be provided between the RF matching circuit and the antenna port for blocking a direct current from entering the RF matching circuit; the second blocking part may be an alternating current blocking part, one end thereof is connected to the detecting port, and the other end is connected to the RF line between the first blocking part and the antenna port; the reference level providing module may be connected between the detecting port and the second blocking part; the detecting port may be configured for detecting level, and determine that the connection of the antenna is normal if the detected level is zero.

### BACKGROUND OF THE INVENTION

1. Field of the Invention

This application relates to a communication field, and more particularly to a communication device and an antenna testing apparatus.

2. Description of the Prior Art

To implement a wireless communication between terminals and other apparatuses, an antenna may be embedded in many terminals for the transmitting and receiving signals.

In a common antenna, a Planar Inverted-F Antenna (PIFA, also called Inverted-F Antenna) has the advantage of small size and simple structure, and thus is widely used. For example, a PIFA is frequently used as a transmitting and receiving antenna of a portable terminal (such as a mobile phone, a notebook, and so on).

With an increasingly improvement of the automation of the production line for the communication products (for example, a portable terminal and the like.), a self-testing of the portable terminal on the production line is becoming more and more important. The self-testing of the portable terminal may make the terminal products implement the test by itself without the usage of any other apparatus, and the problems caused by the improper mounting and assembling of electronic device inside the products may be timely found out by the self-testing. The administrators may adjust and restore the products with problem before shipping based on the result of the self-testing, and thus the repair rate of the electronic products can be significantly reduced, the production automation and the production efficiency can be improved, and the cost for producing and testing can be saved. Up to now, the self-testing of the terminal products may cover more than 90% device pins inside the terminals on the production line used by certain terminal manufacturers.

For the PIFA, there is a grounding point or a ground pin inside such antenna. For the proper working of the PIFA, it is necessary to ensure a normal connection between a radio frequency (RF) part and an antenna port of the terminal. And it is also necessary to ensure that the grounding point and the ground pin inside the antenna be normally grounded. Regarding how to self-test a PIFA in a terminal, it is proposed that there be provided a coupler in the terminal for measuring the antenna, and a dedicated detecting apparatus for determining the measuring result of the coupler, which results in the self-testing of the antenna. Moreover, a plurality of functional modules comprising A/D converting apparatus and D/A converting apparatus are required to be provided for the self-testing of antenna based on the coupler. As a result, such testing measurement not only is at high cost, but also increases the complexity of the terminal modification.

Similarly, no simple and efficient resolution has been proposed for the self-testing of other antenna that comprises the grounding point and the ground pin.

For the problem of high cost and high complexity in self-testing of the antenna that comprises the grounding point in the related art, no efficient resolution has yet been proposed until now.

### SUMMARY OF THE INVENTION

For solving the problem of high cost and high complexity in self-testing of the antenna that comprises the grounding point in the related art, the present invention proposes a communication device and antenna testing apparatus to efficiently save cost and reduce the complexity of the device.

The technical solutions of the present invention may be implemented as follows:

According to an aspect of the present invention, a communication device may be provided. The communication device may be capable of self-testing an antenna provided thereon, wherein the antenna comprises at least one grounding point. The communication device may comprise a radio frequency (RF) matching circuit, an antenna port and the antenna. The RF matching circuit may be connected to the antenna via the antenna port. And the communication device may further comprise a first blocking part, a second blocking part, a detecting port and a reference level providing module, wherein the first blocking part may be provided between the RF matching circuit and the antenna port and may be configured for blocking a direct current from entering the RF matching circuit; the second blocking part may be an alternating current blocking part, one end thereof may be connected to the detecting port, and the other end may be connected to the RF line between the first blocking part and the antenna port; the reference level providing module may be connected between the detecting port and the second blocking part; the detecting port may be configured for detecting level, and determining that the connection of the antenna is normal if the detected level is zero.

Alternatively, the first blocking part may be a capacitance.

Alternatively, the second blocking part may be a resistance or an inductance.

Furthermore, in an aspect, the detecting port may be configured to be in a state of being pulled up.

Alternatively, in another aspect, the communication device may further comprise a level pulling up part, wherein one end of the level pulling up part may be connected to the reference level providing module, and the other end may be connected between the detecting port and the second blocking part.

Preferably, the level pulling up part may be a pulling up resistance.

Furthermore, the detecting port may be a digital port, and may be configured for determining that the connection of the antenna is abnormal if the detected level is 1.

Furthermore, the connection of the antenna being normal indicates that: the connection between the RF line and the antenna port may be normal, the connection between the antenna port and the antenna may be normal, and the grounding point in the antenna may be normally grounded.

According to another aspect of the present invention, an antenna testing apparatus may be provided. The antenna testing apparatus may be configured for implementing self-testing of an antenna that comprises at least one grounding point by a terminal And the terminal may comprise a radio frequency (RF) matching circuit, an antenna port and the antenna. The radio frequency matching circuit may be connected to the antenna via the antenna port. The testing apparatus may comprise a first blocking part, a second blocking part, a detecting port and a reference level providing module. Specifically speaking, the first blocking part may be provided between the RF matching circuit and the antenna port, and may be configured for blocking a direct current from entering the RF matching circuit; the second blocking part may be an alternating current blocking part, one end thereof may be connected to the detecting port, and the other end may be connected to the RF line between the first blocking part and the antenna port; the detecting port may be configured for detecting level, and determining that the connection of the antenna is normal if the detected level is low.

In an aspect, the detecting port may be configured to be in a state of being pulled up.

In another aspect, the apparatus may further comprise a level pulling up part, wherein one end of the level pulling up part may be connected to the reference level providing module, and the other end may be connected between the detecting port and the second blocking part.

According to the present invention, the blocking of the RF circuit may be implemented during the testing by the capacitance, and the blocking of the detecting porting may be implemented during the antenna being in the normally working state by the resistance or the inductance, which may avoid the adverse impact on each other between the testing procedure and the normally working of the antenna, and may also accurately determine whether the antenna is connected normally by detecting the voltage effectuated at the port without the utilization of complex and expensive parts. As a result, the cost can be effectively saved and the complexity of the device can be reduced.

### BRIEF DESCRIPTION OF THE DRAWINGS

FIG. 1 is a structure block diagram of the communication device according to an embodiment of the present invention;

FIG. 2 is a block diagram illustrating the specific structure instance of the communication device as shown in FIG. 1;

FIG. 3 is a structure block diagram of the communication device according to a further embodiment of the present invention;

FIG. 4 is a block diagram illustrating the specific structure instance of the communication device as shown in FIG. 3;

FIG. 5 is a schematic diagram illustrating the abnormal connection of the antenna port in the communication device as shown in FIG. 4;

FIG. 6 is a schematic diagram illustrating the abnormal connection of the grounding point in the antenna in the communication device as shown in FIG. 4;

FIG. 7 is a structure block diagram of a TD-SCDMA/EDGE terminal when the testing solution of the present invention is applied to the terminal.

### DETAILED DESCRIPTION OF THE PREFERRED EMBODIMENTS

For the problem that the antenna that comprises the grounding point can not be tested by a simple and efficient method in the related art, it is considered in the present invention that if the connection of the antenna that comprises the grounding point is abnormal (no matter whether the connection between the antenna and the RF part of the communication device is abnormal or the grounding in the antenna is abnormal), the antenna side is in a state of being suspended (open circuited). The present invention may test the connection of the antenna based on such characteristics. According to the present invention, it may be determined whether the connection of the antenna is normal by a simple judgment on the power level. Such determination not only may provide high accuracy, but also may avoid the adoption of high cost part and complex circuit.

In the following, the embodiments of the present invention will be described in detail in connection with the drawings.

According to an embodiment of the present application, a communication device is provided, which is capable of self-testing an antenna that comprises at least one grounding point provided thereon.

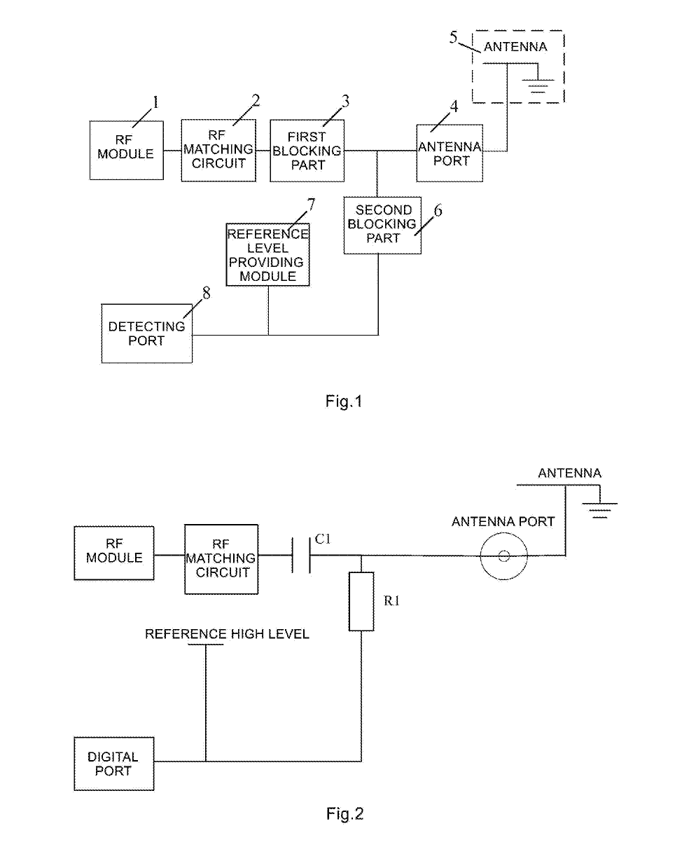

As illustrated in FIG. 1, the communication device usually comprises a RF module 1, a RF matching circuit 2, an antenna port 4 and an antenna 5. And the RF matching circuit 1 is connected to the antenna 5 via the antenna port 4. Here as the structures of the antenna and the communication device are known for those skilled in the art, FIG. 1 only shows that the antenna 5 comprises a grounding point, but does not show how the grounding point and other parts in the antenna are connected and other components of the communication device for the purpose of clarity. For achieving the self-testing of the antenna, the communication device according to the embodiment of the present invention may further comprise a first blocking part 3, a second blocking part 6, a reference level providing module 7 and a detecting port 8.

Specifically, the first blocking part 3 may be provided between the RF matching circuit 2 and the antenna port 4 (may be provided at a position where a RF channel is near the antenna port), which is used for blocking the direct current from entering the RF matching circuit 2; the second blocking part 6 may be an alternating current blocking part (the second block part may also be referred as a RF signal blocking part), one end thereof may be connected to the detecting port 8, and the other end may be connected to a RF line between the first blocking part 3 and the antenna port 4; the reference level providing module 7 may be connected between the detecting port 8 and the second blocking part 6; the detecting port 8 is used for level detecting, and may determine that the connection of the antenna is normal if the detected level is zero.

Here the connection of the antenna being normal means that the RF line is normally connected to the antenna port 4, the antenna port 4 is normally connected to the antenna 5, and the grounding point in the antenna 5 is normally grounded.

As illustrated in FIG. 1, if the RF line connected between the antenna port 4 and the RF matching circuit 2 is normally connected, the antenna port 4 is normally connected to the circuit in the antenna (for example, the feed circuit in the antenna), and the grounding point in the antenna 5 is normally grounded, then the second blocking part 6 may be deemed as being grounded via the antenna 5. In this case, the detecting port 8 may be treated as implementing a pulling down by the second blocking part 6 and the grounded point in the antenna 5. In this case, the state read by the port is 0, i.e., the level detected by the detecting port 8 is a low level (zero level).

In contrast, if the RF line connected between the antenna port 4 and the RF matching circuit 2 is abnormally connected (i.e. open circuited), or the antenna port 4 and the circuit in the antenna (for example, the feed circuit in the antenna) are normally connected (for example, open circuited), or the grounding point in the antenna 5 is normally grounded (abnormally grounded), the second blocking part 6 may be deemed as being open circuited. In this case, the level detected by the detecting port 8 is a high level. Thus, it is determined whether the antenna is normally connected by the simple judgment on the level, and the detecting method can be implemented without adding high cost parts (for example, the coupler) to the communication device in the present invention, which may not only save the cost, but also reduce the labor for modifying the terminal, and thus reduce the complexity of implementation.

In the above communication device, the first blocking part 3 may be any device that can block the direct current while do not impact the RF resistance matching. For example, the first blocking part 3 may be a capacitance. Optionally, the value of the capacitance may be between 20 pF and 80 pF for a common communication system working in a range from 500 MHz to 3 GHz.

The second blocking part (RF signal blocking part) 6 may be any part that can effectively block the alternating current, such as a resistance or an inductance. Preferably, if the second blocking part 6 is an inductance, the value of the inductance should be high enough to ensure that the RF matching is not being impacted. For example, the value of the inductance may be more than 50 nH for a communication system working in a range from 500 MHz to 3 GHz. Considering the cost of implementation, the second blocking part 6 may also be a resistance. No matter whether a high value resistance or a high value inductance is connected, the purpose thereof is for ensuring that the RF resistance of the whole device is high enough (substantially is an open circuit) to avoid the impact on the RF matching when the RF circuit of the communication device works, and thus the impact on the RF matching can be avoided; and the second blocking part 6 may normally conduct a voltage signal when working on low frequency digital signals.

Furthermore, the detecting port 8 may be a digital port, and the detecting port may determine that the connection of the antenna 5 is abnormal if the level detected by the detecting port 8 is 1.

To ensure that the level may be clearly indicated, the detecting port may be configured to be in a pulled up state (for example, in a weakly pulled up state). Accordingly, the second blocking part may be a high value resistance, and the value thereof may be in a range from 20KΩ to 60KΩ or other suitable values. The specific resistance value may be determined based on the weakly pulling up resistance value in the detecting port.

For example, as illustrated in FIG. 2, the first blocking part may be implemented by the capacitance C1, while the second blocking part may be implemented by the resistance R1, and the detecting port may be implemented by the digital port.

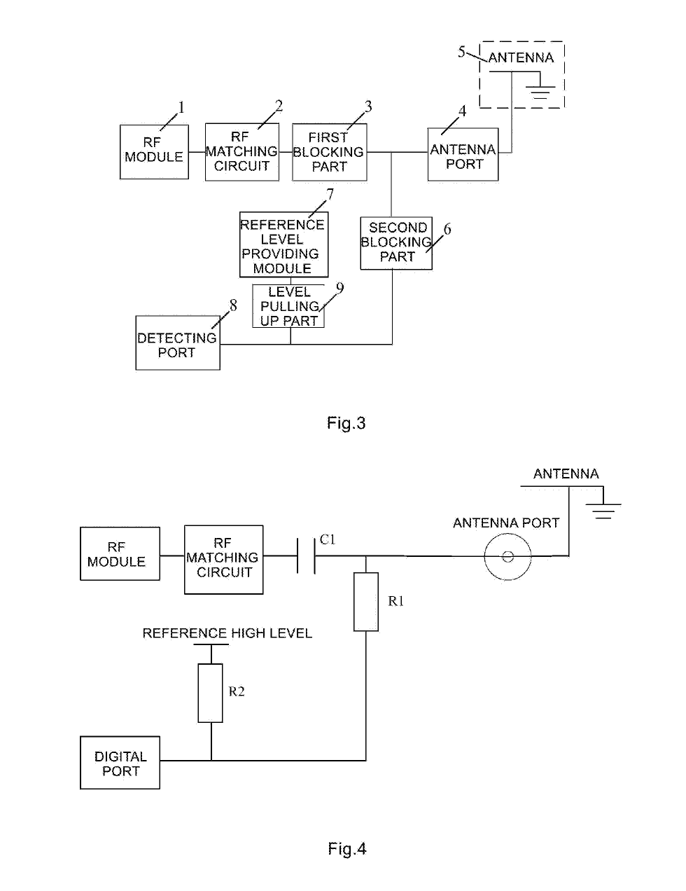

To achieve the accurate detecting of the level, a level pulling up part may be further separately provided in the communication device besides the detecting port being configured to be pulled up. As illustrated in FIG. 3, the communication device may comprise a RF module 1, a RF matching circuit 2, an antenna port 4 and an antenna 5. And the RF matching circuit may be connected to the antenna via the antenna port. In contrast to the communication device according to the former embodiment, the communication device according to the present embodiment may further comprise a level pulling up part 9, in addition to the first blocking part 3, the second blocking part 6, the reference level providing module 7 and the detecting port 8. And the detecting port 8 may be configured to be in the state of being suspended (not pulled up state).

Thus, even though the detecting port may not be configured to be in the state of being pulled up, it is possible to implement the accuracy indication of the level by the level pulling up part, and a misoperation can be avoided.

Specifically, the first blocking part 3 may be provided between the RF matching circuit 2 and the antenna port 4 and is used for blocking the direct current from entering the RF matching circuit 2; the second blocking part 6 may be an alternating current blocking part, one end thereof is connected to the detecting port 8, and the other end is connected to the RF line between the first blocking part 3 and the antenna port 4; one end of the level pulling up part 9 may be connected to the reference level providing part 7, and the other end may be connected between the detecting port 8 and the second blocking part 6; the detecting port 8 may be used for detecting the level, and may determine that the connection of the antenna is normal if the detected level is low.

Similarly, the first blocking part 3 may be a capacitance. The second blocking part 6 may be a resistance or an inductance, the inductance value thereof may be more than 50 nH (or another value); and if the second blocking part 6 is a resistance, the resistance value thereof may be in a range from 20KΩ to 60KΩ, and other resistance values may also be adopted, which would not be numerated herein.

Furthermore, the detecting port may be a digital port, and in case that the detected level is 1, it is determined that the connection of the antenna is abnormal.

Furthermore, the level pulling up part may be a pulling up resistance, and optionally, the value of the resistance may be more than 300KΩ.

For example, as illustrated in FIG. 4, the first blocking part may be implemented by the capacitance C1, the second blocking part may be implemented by R1, the detecting port may be implemented by the digital port, and the level pulling up part may be implemented by R2.

Specifically, the detecting principle of the present embodiment is same as the detecting principle of the former embodiment, and the following explanation is based on the illustration of FIG. 4.

The state of the port that is connected to the resistance R1 may be read by the reading function of the digital port when the self-testing of the antenna connection is being implemented. And the digital port may be deemed as implementing the pulling down by the resistance R1 and the antenna grounding point only if both the antenna port and the grounding point are normally connected. In this case, the state read by the digital port is 0, which indicates that the antenna is normally connected, as illustrated in FIG. 4.

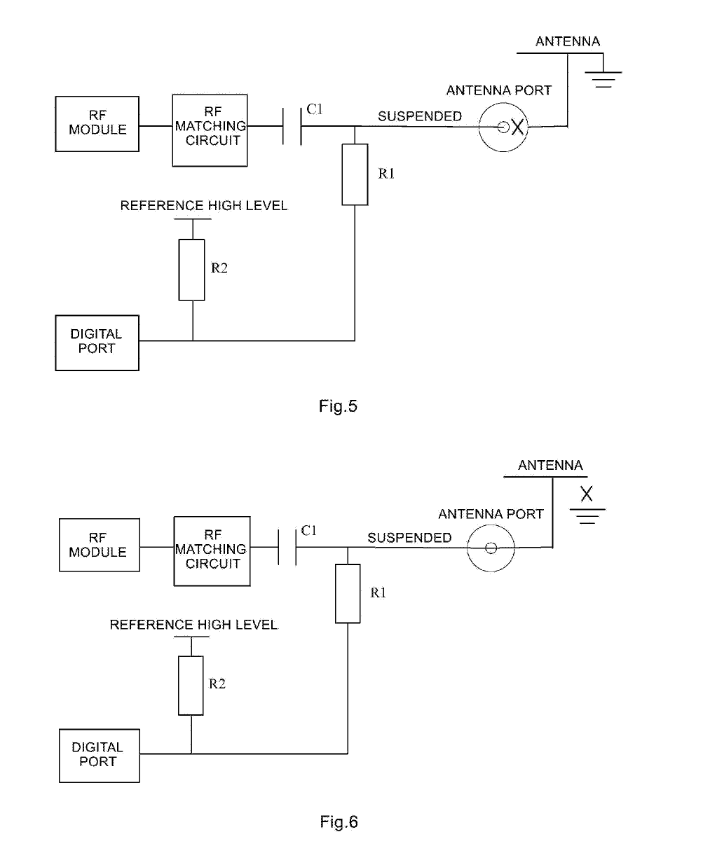

When the antenna port and the antenna feed circuit are abnormally disconnected (as illustrated in FIG. 5) or the antenna grounding point is not grounded (as illustrated in FIG. 6), since one end of the RF line is the antenna open circuit (not grounded by the antenna) and the other end is a direct current blocking capacitance. Therefore, both ends of the RF line are in the state of direct current open circuit, and R1 may be deemed as being suspended. In this case, the state read by the digital port is 1, which indicates that the connection of the antenna is abnormal because of the inner or outer weakly pulling up.

When the antenna is in the state of normally transmitting and receiving, the high value resistance R1 that is connected to the RF line may be deemed as being grounded at one end, and a shunt resistance may be implemented along with the RF line. Since the impedance value of R1 is fairly high, the impact on the RF circuit matching may be neglected. Similarly, the direct current blocking capacitance having reasonable value may be deemed as directly connected with regard to the RF signal, which also may not impact on the RF circuit and the RF performance.

According to the above communication device, it may test whether the connection of the antenna is normal by the simple and low cost parts without the impact on the normal RF operation and the RF performance, which may effectively reduce the cost and the complexity of the implementation.

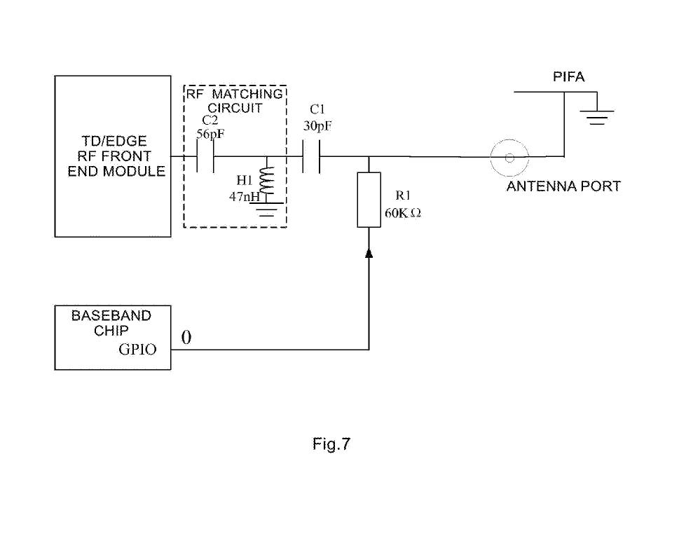

The method for implementing PIFA detecting in the terminal according to the present invention will be described by the example of implementing self-testing in the PIFA of a TD-SCDMA/EDGE dual-mode mobile phone. As illustrated in FIG. 7, the terminal may comprise a TD-SCDMA/EDGE RF front end module (also simply referred as “TD/EDGE RF front end module”, which is equivalent to the RF module). And the terminal baseband hardware may provide a GPIO universal digital port with weakly pulled up (equivalent to the detecting port), which may be configured with the states of reading and writing. When being in the state of reading, it is configured to be in the state of weakly pulled up of 470 KΩ in the port (since the GPIO port itself can be configured to be in the state of weakly pulled up, the terminal as illustrated in FIG. 7 is not necessary to be additionally provided with a level pulling up part). This GPIO port may be connected to the RF line at front of the antenna port via a high value resistance of 60KΩ (equivalent to the second blocking part). Preferably this resistance should be close to the RF line as much as possible. One end of the RF line may be connected to the antenna port, while the other end may be connected to a direct current blocking capacitance of 30 pF (equivalent to the first blocking part) and may be isolated from the RF matching circuit. The terminal may further comprise a RF matching circuit. And the RF matching circuit may further comprise a capacitance C2 and a grounded inductance H1, the capacitance value of C2 may be 56 pF, and the inductance value of H1 may be 47 nH.

When the terminal is in the working state of transmitting and receiving, GPIO port may be configured to be in the state of low level outputting. In this case, the shunt high resistance of 60KΩ and the capacitance in series of 30 pF in the RF line do not impact on the RF matching, and the RF circuit and the antenna can work properly.

When the terminal is in the state of self-testing of the PIFA, the RF circuit does not work. The GPIO port may be configured to be in the state of weakly pulled up inputting, which is used for reading a state of the port. If the PIFA and the grounding point are both normally connected, the GPIO port may be pulled down by the antenna grounding point, and the read port state is 0; if the PIFA port is not connected or the grounding point is not grounded, the GPIO port is suspended and weakly pulled down in the port, and the read port state is 1. As such, the judgment of the antenna connecting state may be implemented by the self-testing of the terminal.

In summary, according to the above technical solutions of the present invention, the blocking of the RF circuit may be implemented during the testing by the capacitance, and the blocking of the detecting porting may be implemented during the antenna being in the normally working state by the resistance or the inductance, which may avoid the impact on each other between the testing procedure and the normally working of the antenna, and may also accurately determines whether the antenna is connected normally by detecting the voltage at the port without the utilization of complex and expensive parts. As a result, the cost can be effectively saved and the complexity of the communication device can be reduced.

The above descriptions are just some preferred embodiments of the present invention and the present invention is not limited thereto. Any modification, equivalent substitution, and modification made under the teaching of the spirit and the principle of the present invention should fall in the protection scope of the present invention.

1. A communication device capable of self-testing an antenna provided thereon, wherein the antenna comprises at least one grounding point, the communication device comprises a radio frequency (RF) matching circuit, an antenna port and the antenna, the RF matching circuit is connected to the antenna via the antenna port, wherein the communication device further comprises a first blocking part, a second blocking part, a detecting port and a reference level providing module, wherein
the first blocking part is provided between the RF matching circuit and the antenna port and is configured for blocking a direct current from entering the RF matching circuit;
the second blocking part is an alternating current blocking part, one end thereof is connected to the detecting port, and the other end is connected to the RF line between the first blocking part and the antenna port;
the reference level providing module is connected between the detecting port and the second blocking part; and
the detecting port is configured for detecting level, and determining that the connection of the antenna is normal if the detected level is zero.

2. The communication device according to claim 1, wherein the first blocking part is a capacitance.

3. The communication device according to claim 1, wherein the second blocking part is a resistance or an inductance.

4. The communication device according to claim 1, wherein the detecting port is configured to be in a state of being pulled up.

5. The communication device according to claim 1, further comprising a level pulling up part, wherein one end of the level pulling up part is connected to the reference level providing module, and the other end is connected between the detecting port and the second blocking part.

6. The communication device according to claim 5, wherein the level pulling up part is a pulling up resistance.

7. The communication device according to claim 4, wherein the detecting port is a digital port, and is configured for determining that the connection of the antenna is abnormal if the detected level is 1.

8. The communication device according to claim 1, wherein the connection of the antenna being normal indicates that:
the connection between the RF line and the antenna port is normal, the connection between the antenna port and the antenna is normal, and the grounding point in the antenna is normally grounded.

9. An antenna testing apparatus for implementing self-testing of an antenna that comprises at least one grounding point by a terminal, wherein the terminal comprises a radio frequency (RF) matching circuit, an antenna port and the antenna, the radio frequency matching circuit is connected to the antenna via the antenna port, wherein the testing apparatus comprises a first blocking part, a second blocking part, a detecting port and a reference level providing module, wherein
the first blocking part is provided between the RF matching circuit and the antenna port and is configured for blocking a direct current from entering the RF matching circuit;
the second blocking part is an alternating current blocking part, one end thereof is connected to the detecting port, and the other end is connected to the RF line between the first blocking part and the antenna port; and
the detecting port is configured for detecting level, and determining that the connection of the antenna is normal if the detected level is low.

10. The testing apparatus according to claim 9, wherein the detecting port is configured to be in a state of being pulled up.

11. The testing apparatus according to claim 9, further comprising a level pulling up part, wherein one end of the level pulling up part is connected to the reference level providing module, and the other end is connected between the detecting port and the second blocking part.
